(19) United States
(12) Patent Application Publication
(10) Pub. No.: US 2025/0293200 A1
(43) Pub. Date: Sep. 18, 2025

(54) LAMINATE MANUFACTURING METHOD, INSULATION MATERIAL, AND LAMINATE

(71) Applicant: Resonac Corporation, Minato-ku, Tokyo (JP)

(72) Inventors: Yuki IMAZU, Minato-ku, Tokyo (JP); Kazuyuki MITSUKURA, Minato-ku, Tokyo (JP); Masaya TOBA, Minato-ku, Tokyo (JP)

(21) Appl. No.: 18/860,688

(22) PCT Filed: Nov. 28, 2022
(86) PCT No.: PCT/JP2022/043814

§ 371 Date: Oct. 28, 2024

(51) Int. Cl. H01L 23/00; B32B 27/20

(52) U.S. Cl. CPC H01L 24/80; B32B 27/20; B32B 2264/10; B32B 2307/206; B32B 2457/14; H01L 2224/80379; H01L 2224/8059; H01L 2224/80686; H01L 2224/80895; H01L 2224/80896

(57) ABSTRACT

A method for manufacturing a stack, includes forming a first insulation layer on a first support substrate, the first insulation layer including a first thermosetting resin and first inorganic oxide particles; and bonding a first surface of the first insulation layer to a second surface of a second insulation layer including a second thermosetting resin. In this manufacturing method, the second insulation layer includes substantially no inorganic oxide particles or includes second inorganic oxide particles in a content smaller than that of the first inorganic oxide particles included in the first insulation layer.

### TECHNICAL FIELD

The present disclosure relates to a method for manufacturing a stack, an insulation material, and a stack. The present disclosure relates to, for example, a method for manufacturing a stack (semiconductor device) including a semiconductor chip, an insulation material used in the method for manufacturing a stack, and a stack including a semiconductor chip.

### BACKGROUND ART

In recent years, various methods of direct bonding technology for directly bonding metal connection terminals to each other have been proposed as a method for connecting connection terminals in connection between semiconductor chips stacked in the vertical direction or in connection between a semiconductor package such as a silicon interposer and a semiconductor chip (for example, refer to Patent Literature 1 to 3). In the connection method by the direct bonding technology, not only the connection terminals but also the insulation layers disposed around the connection terminals are bonded to each other. As the insulation layer, an inorganic insulation material such as silicon oxide is used.

### CITATION LIST

### Patent Literature

Patent Literature 1: US Patent Application Publication No. 2020/0135636

Patent Literature 2: US Patent Application Publication No. 2020/0135683

Patent Literature 3: US Patent Application Publication No. 2020/0135684

### SUMMARY OF INVENTION

### Technical Problem

In the direct bonding technology using an inorganic insulation material as an insulation layer, a defect may occur in bonding between the insulation layers due to an influence of cutting chips (debris) generated in a step such as dicing or unevenness on a surface. Therefore, it is considered that debris and the like are embedded in an organic resin material or unevenness on the surface are suppressed during heat molding by the direct bonding technology using an organic insulation material such as a resin material that is softer and less expensive than an inorganic material as the insulation layer. On the other hand, since the organic insulation material is more likely to thermally expand than the inorganic insulation material and may cause positional displacement, it is considered that an inorganic filler is added to the organic insulation material to lower the thermal expansion coefficient of the insulation material. However, when the inorganic filler is added, the ability to embed debris or the like, suppress surface unevenness, and the bonding force between the organic insulation layers are reduced. Therefore, it is desired to increase the bonding strength between the organic insulation layers while preventing positional displacement when the organic insulation layers are bonded to each other.

### Solution to Problem

As one aspect, the present disclosure provides a method for manufacturing a stack. This method for manufacturing a stack includes: forming a first insulation layer on a first support substrate, the first insulation layer including a first thermosetting resin and first inorganic oxide particles; and bonding a first surface of the first insulation layer to a second surface of a second insulation layer including a second thermosetting resin. In this manufacturing method, the second insulation layer includes substantially no inorganic oxide particles or includes second inorganic oxide particles in a content smaller than that of the first inorganic oxide particles included in the first insulation layer.

In the method for manufacturing a stack, while the first insulation layer includes the thermosetting resin and the inorganic oxide particles, the second insulation layer includes the thermosetting resin but includes no inorganic oxide particles, or includes the inorganic oxide particles less than the first insulation layer. Then, the first and second insulation layers are bonded to each other. In this case, the thermal expansion coefficient of the first insulation layer is decreased by the inorganic oxide particles included in the first insulation layer. On the other hand, the second insulation layer includes no inorganic oxide particles or includes inorganic oxide particles in a small amount, and thus it is possible to embed debris, suppress the surface unevenness, and improve the bonding force between the insulation layers, by the second insulation layer. According to the method for manufacturing a stack, it is possible to increase the bonding strength between insulation layers while preventing positional displacement when the insulation layers are bonded to each other. The phrase “include(s) substantially no inorganic oxide particles” as used herein includes a case where an extremely small amount of inorganic oxide is contained in the second insulation layer.

In the above-described method for manufacturing a stack, a content of the second inorganic oxide particles in a second insulation material forming the second insulation layer is preferably one fifth (⅕) or less of a content of the first inorganic oxide particles included in a first insulation material forming the first insulation layer. In this case, the second insulation layer can further embed debris, suppress the surface unevenness, and improve the bonding force between the insulation layers.

In the above-described method for manufacturing a stack, the content of the second inorganic oxide particles in the second insulation material forming the second insulation layer is preferably 5% by volume or less. In this case, the second insulation layer can further embed debris, suppress the surface unevenness, and improve the bonding force between the insulation layers.

In the above-described method for manufacturing a stack, the second insulation material forming the second insulation layer preferably includes substantially no inorganic oxide particles. In this case, the second insulation layer can more reliably embed debris, suppress the surface unevenness, and improve the bonding force between the insulation layers.

In the above-described method for manufacturing a stack, the first insulation material including the first thermosetting resin and the first inorganic oxide particles is preferably adjusted to have a thermal expansion coefficient smaller than that of the second insulation material forming the second insulation layer. In this case, the thermal expansion coefficient in the first insulation layer can be reduced, and thus positional displacement due to thermal expansion can be prevented. Accordingly, it is possible to obtain a stack with high bonding accuracy. In addition, in a case where a wiring such as copper (Cu) is provided in the stack, the expansion of the insulation material including the thermosetting resin or the like may be larger than the expansion of the wiring, and the wiring may not be able to follow the expansion of the insulation layer, and a defect may occur in the bonding between the wirings. However, according to this manufacturing method, by reducing the thermal expansion coefficient of the first insulation material, a difference in thermal expansion between the insulation material and the wiring can be reduced, and bonding failure between the wirings can be prevented.

In the above-described method for manufacturing a stack, the first insulation material including the first thermosetting resin and the first inorganic oxide particles is preferably adjusted to have a thermal expansion coefficient of 40×10⁻⁶/K or less. In this case, the thermal expansion coefficient in the first insulation layer can be reduced, and thus positional displacement due to thermal expansion can be prevented. Accordingly, it is possible to obtain a stack with high bonding accuracy. In addition, in a case where a wiring such as copper (Cu) is provided in the stack, the expansion of the insulation material including the thermosetting resin or the like may be larger than the expansion of the wiring, and the wiring may not be able to follow the expansion of the insulation layer, and a defect may occur in the bonding between the wirings. However, according to this manufacturing method, by reducing the thermal expansion coefficient of the first insulation material, a difference in thermal expansion between the insulation material and the wiring can be reduced, and bonding failure between the wirings can be prevented.

In the above-described method for manufacturing a stack, the content of the first inorganic oxide particles in the first insulation material including the first thermosetting resin and the first inorganic oxide particles is preferably 15% by volume to 70% by volume. In this case, the thermal expansion coefficient in the first insulation layer can be reduced by containing the inorganic oxide particles, and thus positional displacement due to thermal expansion can be prevented. Accordingly, it is possible to obtain a stack with high bonding accuracy. In addition, in a case where a wiring such as copper (Cu) is provided in the stack, the expansion of the insulation material including the thermosetting resin or the like may be larger than the expansion of the wiring, and the wiring may not be able to follow the expansion of the insulation layer, and a defect may occur in the bonding between the wirings. However, according to this manufacturing method, by reducing the thermal expansion coefficient of the first insulation material, a difference in thermal expansion between the insulation material and the wiring can be reduced, and bonding failure between the wirings can be prevented.

The above-described method for manufacturing a stack may further include planarizing the first surface of the first insulation layer. In the planarizing the first insulation layer, the first insulation layer may be polished such that the arithmetic average roughness of the first surface is 50 nm or less. When inorganic oxide particles are included in the insulation layer, the surface roughness of the insulation layer may become rough, but in the present manufacturing method, the first insulation layer is polished before bonding. Accordingly, it is possible to more reliably increase the accuracy and bonding strength when the first insulation layer is bonded to the second insulation layer. As a result, it is possible to more reliably increase the accuracy and bonding strength when the first insulation layer is bond to the second insulation layer. The arithmetic average roughness used here is an arithmetic average roughness (Ra) defined in JIS B 0601 2001. The second insulation layer may also be polished.

In the above-described method for manufacturing a stack, the first support substrate may include an inorganic interposer made of an inorganic material or an organic interposer made of an organic material including inorganic oxide particles. In this case, by reducing the thermal expansion coefficient of the insulation layer on the interposer side, the difference in thermal expansion coefficient between the insulation layer and the interposer can be reduced, and defects in the interposer during package assembly, such as warpage, cracks, defective mounting, defective terminal connection, defective insulation layer formation, and interfacial peeling, can be eliminated. In addition, by reducing the thermal expansion coefficient of the insulation layer on the interposer side, the difference in thermal expansion coefficient between the insulation layer and the interposer can be reduced, and defects as a stack (or semiconductor device), such as deformation of wiring, connection breakdown, material peeling, wiring short, and material failure, can be eliminated.

In the above-described method for manufacturing a stack, a semiconductor chip may be attached to a surface of the second insulation layer on a side opposite to the second surface. In this case, the insulation layer on the semiconductor chip side includes no inorganic oxide particles or includes a small amount of inorganic oxide particles, and it is possible to prevent adhesion of the particles to the semiconductor chip and occurrence of a connection failure or the like.

The above-describe method for manufacturing a stack may further include planarizing the first surface of the first insulation layer; forming the second insulation layer including the second thermosetting resin on the second support substrate, and planarizing the second surface of the second insulation layer. In the bonding, the planarized first surface may be bonded to the planarized second surface. When inorganic oxide particles are included in the insulation layer, the surface roughness of insulation layer may become rough, but in the present manufacturing method, the insulation layer is planarized by polishing or the like before bonding. Accordingly, it is possible to further increase the bonding strength between the first insulation layer and the second insulation layer.

The above-described method for manufacturing a stack preferably further includes irradiating the second surface of the second insulation layer with ultraviolet rays. In this case, the surface of the resin material forming the second insulation layer reacts with ozone generated by the irradiation with the ultraviolet rays, the surface free energy increases, and a highly reactive functional group is generated on the surface of the second insulation layer. In other words, the cured product of the thermosetting resin forming the second insulation layer is in a state close to that before curing. Accordingly, it is possible to further increase the bonding strength between the first insulation layer and the second insulation layer. In the case of irradiation with ultraviolet rays, unlike the plasma treatment, the second surface of the second insulation layer is not roughened, and thus bonding between the first insulation layer and the second insulation layer is not hindered. However, surface treatment using plasma treatment may be performed. In addition, in this manufacturing method, the bonding between the first insulation layer and the second insulation layer is enhanced by ultraviolet irradiation as described above, the heating temperature at the time of bonding the first insulation layer to the second insulation layer can be lowered as compared with the conventional case, or the heating time can be shortened. Accordingly, it is possible to simplify the bonding process and to decrease the influence of heating on the stack (or semiconductor device).

In the method for manufacturing a stack, in the bonding the first surface to the second surface, the first insulation layer and the second insulation layer may be bonded to each other by heating them at 250° C. or lower. In this case, it is possible to suppress the influence of heating on the stack (or the semiconductor device).

In the above-described method for manufacturing a stack may further include forming a first wiring electrode on the first support substrate. In the forming the first insulation layer, the first wiring electrode may be encapsulated with the first insulation material including the first thermosetting resin and the first inorganic oxide particles. As a result, the first wiring electrode is protected by the first insulation material.

In the above-described method for manufacturing a stack may further include forming a second wiring electrode on the second support substrate; and forming the second insulation layer on the second support substrate to encapsulate second wiring electrode with the second insulation material including the second thermosetting resin. When the first surface of the first insulation layer is bonded to the second surface of the second insulation layer, a connection terminal of the first wiring electrode may be bonded to a connection terminal of the second wiring electrode in the bonding. In this case, the first connection terminal and the second connection terminal can be bonded to each other more reliably.

The present disclosure provides, as another aspect, an insulation material. This insulation material is an insulation material used in the method for manufacturing a stack, including forming a first insulation layer on a first support substrate using an insulation material including a first thermosetting resin and first inorganic oxide particles, and bonding a first surface of the first insulation layer to a second surface of a second insulation layer including a second thermosetting resin. In the manufacturing method in which the insulation material is used, the second insulation layer includes substantially no inorganic oxide particles or includes second inorganic oxide particles in a content smaller than that of the first inorganic oxide particles included in the first insulation layer.

This insulation material includes a thermosetting resin and inorganic oxide particles, and a first insulation layer formed using this insulation material is bonded to a second insulation layer. In this case, the thermal expansion coefficient of the first insulation layer is decreased by the inorganic oxide particles includes in the first insulation layer. Accordingly, it is possible to prevent positional displacement when the insulation layers are bonded to each other.

It is preferable that the above-described insulation material is adjusted to have a linear expansion coefficient of 40×10⁻⁶/K or less. In this case, the thermal expansion coefficient of the first insulation layer is more reliably decreased. Accordingly, it is possible to more reliably prevent positional displacement when the insulation layers are bonded to each other.

In the above-described insulation material, the content of the first inorganic oxide particles in the insulation material may be 15% by volume to 70% by volume. In this case, the thermal expansion coefficient of the first insulation layer is more reliably decreased. Accordingly, it is possible to more reliably prevent positional displacement when the insulation layers are bonded to each other.

The present disclosure provides, as another aspect, an insulation material. This insulation material is an insulation material used in the method for manufacturing a stack, including forming a first insulation layer including a first thermosetting resin and first inorganic oxide particles, on a first support substrate, and bonding a first surface of the first insulation layer to a second surface of a second insulation layer made from the insulation material including a second thermosetting resin. In the manufacturing method in which the insulation material is used, the second insulation layer includes substantially no inorganic oxide particles or includes second inorganic oxide particles in a content smaller than that of the first inorganic oxide particles included in the first insulation layer.

The other insulation material includes the thermosetting resin but includes no the inorganic oxide particles, or includes the inorganic oxide particles less than the first insulation layer, and the second insulation layer formed by using this insulation material is bonded to the first insulation layer. In this case, the second insulation layer can embed debris, suppress the surface unevenness, and improve the bonding force between the insulation layers. Accordingly, the bonding strength between the insulation layers can be enhanced.

The above-described other insulation material preferably has a lower elastic modulus than a material forming the first insulation layer when heated to at least 300° C. In this case, the second insulation layer can further embed debris, suppress the surface unevenness, and improve the bonding force between the insulation layers. Accordingly, the bonding strength between the insulation layers can be further enhanced.

In the above-described other insulation material, the content of the second inorganic oxide particles in the insulation material may be 5% by volume or less. In this case, the second insulation layer can further embed debris, suppress the surface unevenness, and improve the bonding force between the insulation layers. Accordingly, the bonding strength between the insulation layers can be further enhanced.

As still another aspect, the present disclosure provides a stack. This stack includes a first support substrate; a first insulation layer formed on the first support substrate, the first insulation layer including a cured product of a first thermosetting resin and first inorganic oxide particles and; and a second insulation layer bonded to the first insulation layer, the second insulation layer including a cured product of a second thermosetting resin. The second insulation layer includes substantially no inorganic oxide particles or includes second inorganic oxide particles in a content smaller than that of the first inorganic oxide particles included in the first insulation layer.

In this stack, while the first insulation layer includes the cured product of the thermosetting resin and the inorganic oxide particles, the second insulation layer includes the cured product of the thermosetting resin but includes no inorganic oxide particles, or includes the inorganic oxide particles less than the first insulation layer. The first and second insulation layers are bonded to each other. In this case, the thermal expansion coefficient of the first insulation layer is decreased by the inorganic oxide particles included in the first insulation layer. On the other hand, the second insulation layer includes no inorganic oxide particles or includes inorganic oxide particles in a small amount, and thus it is possible to embed debris, suppress the surface unevenness, and improve the bonding force between the insulation layers by the second insulation layer. As described above, it is possible to obtain a stack in which the bonding strength between the insulation layers is increased while preventing the positional displacement when the insulation layers are bonded to each other.

In the above-described stack, the content of the second inorganic oxide particles in the second insulation layer may be 5% by volume or less. In this case, the stack in which the second insulation layer further embed debris, suppress the surface unevenness, and improve the bonding force between the insulation layers can be obtained.

The above-described stack may further include a semiconductor chip disposed on a surface of the second insulation layer opposite to a surface bonded to the first insulation layer.

In the above-described stack, the content of the first inorganic oxide particles in the first insulation layer may be 15% by volume to 70% by volume. In this case, the thermal expansion coefficient in the first insulation layer can be reduced by containing the inorganic oxide particles, the stack in which positional displacement due to thermal expansion is prevented can be obtained. Accordingly, it is possible to obtain the stack with high bonding accuracy. In addition, in a case where a wiring such as copper (Cu) is provided in the stack, the expansion of the insulation material containing the thermosetting resin or the like may be larger than the expansion of the wiring, and the wiring may not be able to follow the expansion of the insulation layer, and a defect may occur in the bonding between the wirings. However, according to this stack, by reducing the thermal expansion coefficient of the first insulation material, a difference in thermal expansion between the insulation material and the wiring can be reduced, and the stack in which bonding failure between the wirings is prevented can be obtained.

The above-described stack may further include a first wiring electrode that is at least partially disposed in the first insulation layer and has a connection terminal exposed from a first surface of the first insulation layer, which is bonded to the second insulation layer; and a second wiring electrode that is at least partially disposed in the second insulation layer, and has a connection terminal exposed from a second surface of the second insulation layer, which is bonded to the first insulation layer. In this stack, the connection terminal of the first wiring electrode may be bonded to the connection terminal of the second wiring electrode.

### Advantageous Effects of Invention

According to the present disclosure, it is possible to provide a stack in which the bonding strength between insulation layers is increased while preventing positional displacement when the insulation layers are bonded to each other.

### BRIEF DESCRIPTION OF DRAWINGS

FIG. 1 is a cross-sectional view showing an example of a stack.

FIG. 2 is an enlarged cross-sectional view showing a connection portion II in the stack shown in FIG. 1.

FIG. 3 is a view for describing an outline of a connection method when the stack shown in FIG. 1 is manufactured.

FIG. 4 is a cross-sectional view showing another example of the stack.

FIG. 5 is an enlarged cross-sectional view showing a connection portion V in the stack shown in FIG. 4.

FIG. 6 is a view for describing an outline of a connection method when the stack shown in FIG. 4 is manufactured.

FIGS. 7A to 7C are views showing a method for manufacturing first and second members used in manufacturing the stack.

FIGS. 8A to 8C are views showing a method for manufacturing the first and second members used in manufacturing the stack, and show steps following FIGS. 7A to 7C.

FIGS. 9A to 9D are views showing a method for manufacturing the first member used in manufacturing the stack, and show steps following FIGS. 8A to 8C.

FIGS. 10A to 10C are views showing a method for manufacturing the second member used in manufacturing the stack, and show steps following FIGS. 8A to 8C.

FIGS. 11A and 11B are views showing a stack manufacturing method.

FIGS. 12A to 12C are views showing the stack manufacturing method.

FIG. 13A is a cross-sectional view showing the stack manufactured by a manufacturing method different from the present embodiment, and FIG. 13B is a cross-sectional view showing a stack manufactured by a manufacturing method according to the present embodiment.

FIGS. 14A to 14C are views showing a stack manufacturing method different from the present embodiment and an influence of thermal expansion in a stack manufactured by the manufacturing method.

FIGS. 15A and 15B are views for describing a situation of embedding of a foreign substance by the manufacturing method according to the present embodiment.

FIG. 16 is a table showing a bonding force (shear strength) in the stack manufacturing method according to the present embodiment.

### DESCRIPTION OF EMBODIMENTS

Hereinafter, embodiments according to the present invention will be described in detail with reference to the drawings. In the following description, the same or corresponding parts will be denoted by the same reference numerals, and redundant description thereof will be omitted. Unless otherwise specified, the positional relationship such as up, down, left, and right is based on the positional relationship shown in the drawings. The use of the terms “left”, “right”, “front”, “back”, “up”, “down”, “above”, “below” and the like in the description and claims of the present specification is intended for description and is not necessarily meant to be a permanent relative position thereof. The dimensional ratios in the drawings are not limited to the shown ratios.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as an intended action of the step is achieved. In the present specification, a numerical range indicated using “A to B” indicates a range including numerical values A and B described before and after “to” as a minimum value and a maximum value, respectively.

### An Example of Stack

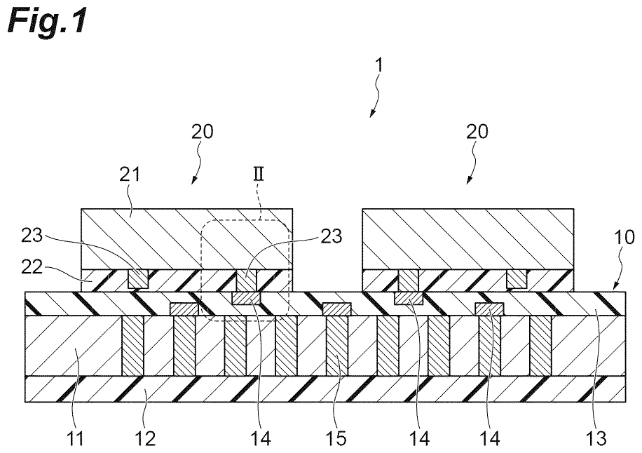

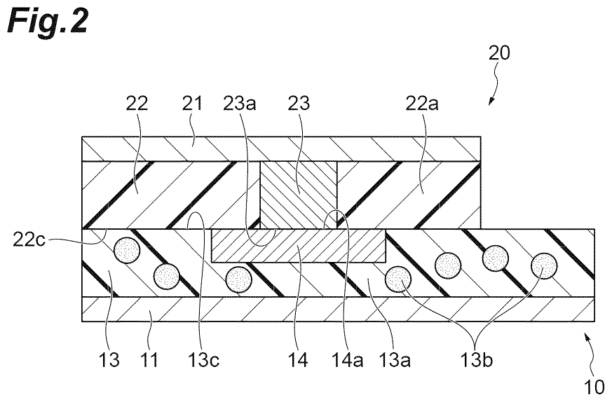

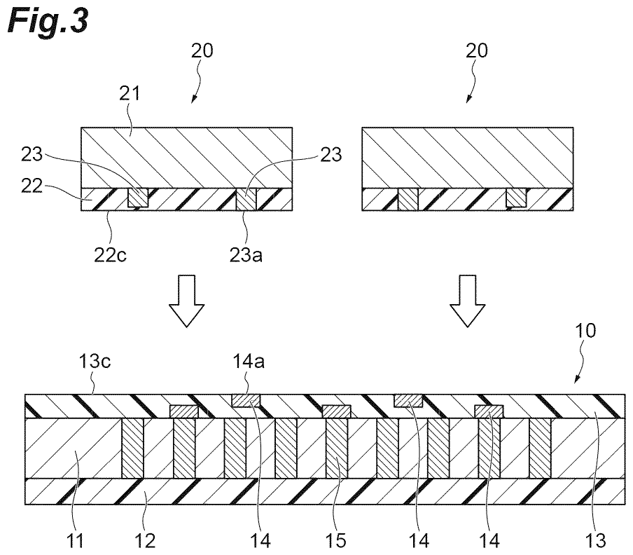

An example of a stack will be described with reference to FIG. 1 to FIG. 3. FIG. 1 is a cross-sectional view showing an example of a stack. FIG. 2 is an enlarged cross-sectional view showing a connection portion II in the stack shown in FIG. 1. FIG. 3 is a view for describing an outline of a connection method when the stack shown in FIG. 1 is manufactured. As shown in FIGS. 1 and 2, a stack 1 is a semiconductor device including a first member 10 and a second member(s) 20. The first member 10 includes an interposer substrate 11 (first support substrate), an insulation layer 12, an insulation layer 13 (first insulation layer), and wiring electrodes 14. The second member 20 includes a semiconductor chip 21, an insulation layer 22 (second insulation layer), and wiring electrodes 23.

The interposer substrate 11 is, for example, a silicon (Si) interposer substrate. The interposer substrate 11 is provided with through silicon vias (TSVs) 15 to each electrically connect upper and lower semiconductor chips, wiring, and the like of the interposer substrate 11. The interposer substrate 11 may be a substrate formed of an inorganic material (e.g. a glass material) other than silicon. The thickness of the interposer substrate 11 is not particularly limited, and is, for example, 0.2 mm to 2.0 mm. When the thickness of the interposer substrate 11 is 0.2 mm or more, the handleability of the substrate can be improved. Since the thickness of the interposer substrate 11 is 2.0 mm or less, the material cost can be decreased. The interposer substrate 11 may have a panel shape or a wafer shape.

The insulation layer 12 is an insulation layer provided on the lower side of the interposer substrate 11. The insulation layer 12 is formed of an organic insulation material, and the organic insulation material may contain the inorganic filler or may contain no inorganic filler. The insulation layer 12 may be provided with wiring electrodes (not shown) each connected to the TSV 15.

The insulation layer 13 is an organic insulation layer that contains a cured product 13a of a thermosetting resin (a cured product of a first thermosetting resin) and inorganic oxide particles 13b (first inorganic oxide particles) and is formed on the interposer substrate 11 (refer to FIG. 2). The thickness of the insulation layer 13 may be, for example, 10 μm to 300 μm. When the thickness of the insulation layer 13 is 10 μm or more, it is possible to ensure the insulating property of the wiring electrodes 14 and to ensure the bonding force when the insulation layer 13 is bonded to the organic insulation layer 22. When the thickness of the insulation layer 13 is 300 μm or less, the entire thickness of the stack 1 can be reduced. The above-described wiring electrodes 14 are embedded and protected in the insulation layer 13 such that a connection terminal 14a of each wiring electrode 14 is exposed from a surface 13c (first surface) of the insulation layer 13 on the side bonded to the insulation layer 22.

The thermosetting resin used for the insulation layer 13 is not particularly limited, and is, for example, a thermosetting resin such as an epoxy resin, an acrylic resin, a methacrylic resin, a maleimide resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, or a melamine resin. Among them, the thermosetting resin used for the insulation layer 13 is preferably an epoxy resin.

The inorganic oxide particles contained in the insulation layer 13 are not particularly limited, and are, for example, inorganic fillers such as silica (SiO₂), alumina (Al₂O₃), titania (TiO₂), tantalum oxide (Ta₂O₅), zirconia (ZrO₂), and zinc oxide (ZnO). The inorganic oxide particles may be used alone or in combination of two or more types thereof. As an example, the inorganic oxide particles contained in the insulation layer 13 are silica fillers.

The content of the inorganic oxide particles contained in the insulation layer 13 is, for example, 15% by volume to 70% by volume with respect to the total volume of the insulation layer 13. When the content of the inorganic oxide particles is 15% by volume or more of the total volume, the ratio of the cured product of the thermosetting resin contained in the insulation layer 13 is reduced to suppress the linear expansion coefficient (CTE) of the insulation layer 13, and it is possible to reduce warpage when the heat is applied to the stack 1. When the content of the inorganic oxide particles is 70% by volume or less of the total volume, the bonding region between the thermosetting resins can be sufficiently ensured, and the bonding strength between the insulation layer 13 and the insulation layer 22 can be increased.

The wiring electrode 14 is a minute electrode formed on the interposer substrate 11. The insulation layer 13 is provided with a plurality of wiring electrodes 14. When formed by plating or the like, the wiring electrode 14 may include a seed layer part and a plated part. The wiring electrode 14 is formed of, for example, a conductive material such as copper (Cu). The wiring electrode 14 may be an electrode pin. The wiring electrode 14 may be connected to the TSV 15 or may be connected to the wiring electrode 23 of the second member 20.

The semiconductor chip 21 is, for example, a logic IC or a memory IC.

The insulation layer 22 is an insulation layer that contains a cured product 22a of a thermosetting resin (a cured product of a second thermosetting resin) and is provided on the lower side of the semiconductor chip 21. In other words, the semiconductor chip 21 is disposed on the surface of the insulation layer 22 opposite to the surface bonded to the insulation layer 13. Similarly to the insulation layer 13, the thickness of the insulation layer 22 may be, for example, 10 μm to 300 μm, or may be thinner than the insulation layer 13. The wiring electrodes 23 are embedded and protected in the insulation layer 22 such that each connection terminal 23a is exposed from a surface 22c (second surface) of the insulation layer 22 on the side bonded to the insulation layer 13. The thermosetting resin used for the insulation layer 22 may be the same as the thermosetting resin used for the insulation layer 13, and is not particularly limited, but for example, an epoxy resin can be used.

Unlike the insulation layer 13, the insulation layer 22 contains substantially no inorganic oxide particles. However, the insulation layer 22 may have a form in which some inorganic oxide particles (second inorganic oxide particles) are contained in the cured product 22a of the thermosetting resin, and in this case, the insulation layer 22 may contain inorganic oxide particles having a content smaller than that of the inorganic oxide particles 13b contained in the insulation layer 13. For example, the content of the inorganic oxide particles contained in the insulation layer 22 may be one fifth (⅕) or less of the content of the inorganic oxide particles 22b contained in the insulation layer 22. Alternatively, the content of the inorganic oxide particles contained in the insulation layer 22 may be, for example, 5% by volume or less with respect to the total volume of the insulation layer 22. The phrase “contain substantially no inorganic oxide particles” as used herein includes a case where an extremely small amount of inorganic oxide is contained in the insulation layer 22.

The wiring electrode 23 is a minute electrode formed on the semiconductor chip 21 (lower surface). A plurality of wiring electrodes 23 are provided on the semiconductor chip 21, and are electrically connected to connection terminals of the semiconductor chip 21. When formed by plating or the like, the wiring electrode 23 may include a seed layer part and a plated part. The wiring electrode 23 is formed of, for example, a conductive material such as copper (Cu). The wiring electrode 23 may be an electrode pin. As described above, one end of the wiring electrode 23 may be electrically connected to the connection terminal of the semiconductor chip 21, and the other end may be connected to the wiring electrode 14 or the like of the first member 10.

In the stack 1, the wiring electrodes 14 and the wiring electrodes 23 are provided in each of the insulation layers 13 and 22 to correspond to each other, and when bonded as shown in FIG. 3, the connection terminals 14a and the connection terminals 23a are bonded to each other. The cured products 13a and 22a of the thermosetting resin contained in the insulation layers 13 and 22 are also bonded to each other. In the stack 1, while the insulation layer 13 contains the cured product 13a of the thermosetting resin and the inorganic oxide particles 13b, the insulation layer 22 contains the cured product 22a of the thermosetting resin but contains no inorganic oxide particles, or contains the inorganic oxide particles less than the insulation layer 13, and the insulation layers 13 and 22 are bonded to each other. Therefore, the thermal expansion coefficient of the insulation layer 13 is suppressed by the inorganic oxide particles contained in the insulation layer 13. On the other hand, since the insulation layer 22 contains no inorganic oxide particles or contains inorganic oxide particles in a small amount, it is possible to embed debris, suppress the surface unevenness, and improve the bonding force between the insulation layers 13 and 22 by the insulation layer 22. As described above, in the stack 1, it is possible to obtain a stack in which the bonding strength between the insulation layers is increased while preventing the positional displacement when the insulation layers are bonded to each other.

In the stack 1, contrary to the above-described form, an aspect in which the insulation layer 13 of the first member 10 contains substantially no inorganic oxide particles (or an aspect in which the inorganic oxide particles are contained in a content smaller than that of the inorganic oxide particles contained in the insulating layer 22) may be adopted. In this case, the insulation layer 22 of the second member 20 may contain inorganic oxide particles, and the content of the inorganic oxide particles contained in the insulation layer 22 may be, for example, 15% by volume to 70% by volume with respect to the total volume of the insulation layer 22. That is, in this modification example, the aspect in which the insulation layer 13 of the first member 10 contains the inorganic oxide particles and the aspect in which the insulation layer 22 of the second member 20 contains the inorganic oxide particles are reversed. Even in such a modification example, the same operation and effect as described above can be obtained.

### Another Example of Stack

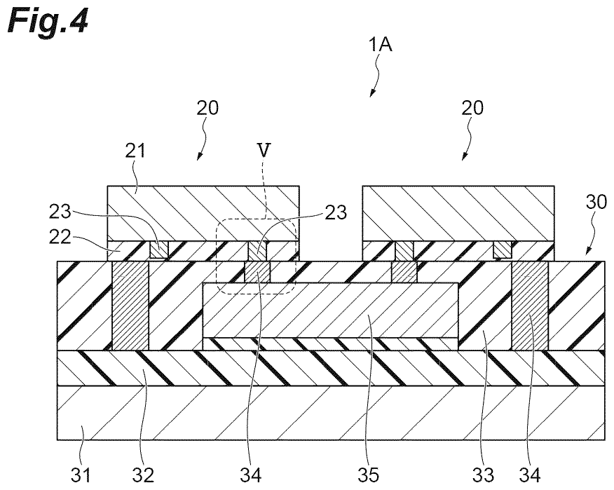

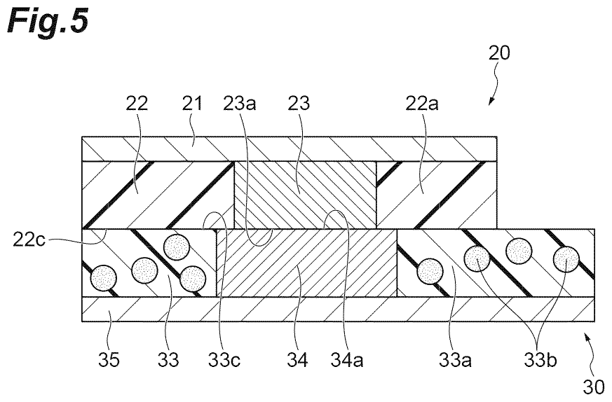

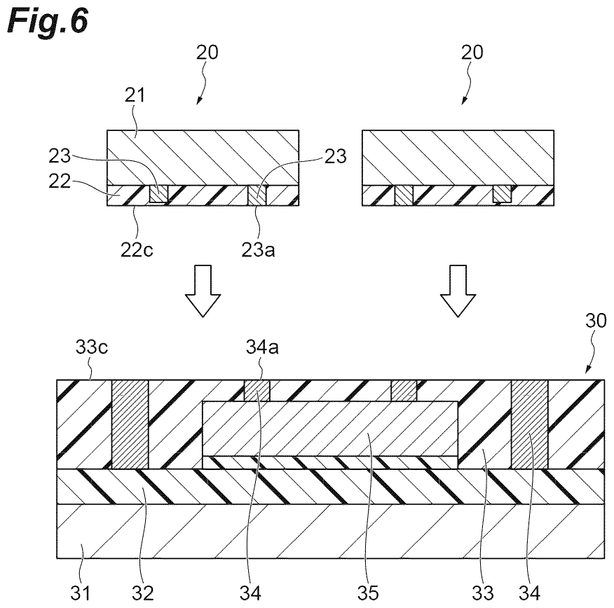

Another example of the stack will be described with reference to FIG. 4 to FIG. 6. FIG. 4 is a cross-sectional view showing another example of the stack. FIG. 5 is an enlarged cross-sectional view showing a connection portion V in the stack shown in FIG. 4. FIG. 6 is a view for describing an outline of a connection method when the stack shown in FIG. 4 is manufactured. As shown in FIGS. 4 and 5, a stack 1A is a semiconductor device including a first member 30 and the second member 20. The first member 30 includes a substrate 31 (first support substrate), an insulation layer 32, an insulation layer 33 (first insulation layer), wiring electrodes 34, and a semiconductor chip 35. The first member 30 may be an organic interposer. Similarly to the stack 1 shown in FIG. 1, the second member 20 includes the semiconductor chip 21, the insulation layer 22 (second insulation layer), and the wiring electrodes 23.

The substrate 31 is, for example, a glass substrate or an organic substrate. The thickness of the substrate 31 is not particularly limited, and is, for example, 0.7 mm to 1.5 mm. When the thickness of the substrate 31 is 0.7 mm or more, handleability of the substrate can be improved. Since the thickness of the substrate 31 is 1.5 mm or less, the material cost can be decreased. The substrate 31 may have a panel shape or a wafer shape.

The insulation layer 32 is an insulation layer provided on the substrate 31. The insulation layer 32 is formed of an organic insulation material, and the organic insulation material may contain the inorganic filler or may contain no inorganic filler. The insulation layer 32 is a layer thinner than the insulation layer 33 to be described later.

The insulation layer 33 is an organic insulation layer that contains a cured product 33a of a thermosetting resin (a cured product of a first thermosetting resin) and inorganic oxide particles 33b (first inorganic oxide particles) and is formed on the substrate 31 via the insulation layer 32 (refer to FIG. 5). The insulation layer 33 also functions as a encapsulant layer that encapsulates the semiconductor chip 35 mounted on the substrate 31. The thickness of the insulation layer 33 may be, for example, 50 μm to 300 μm. When the thickness of the insulation layer 33 is 50 μm or more, it is possible to ensure the insulating property of the wiring electrodes 34 and to ensure the bonding force when the insulation layer 33 is bonded to the insulation layer 22. When the thickness of the insulation layer 33 is 300 μm or less, the entire thickness of the stack 1A can be reduced. The above-described wiring electrodes 34 are embedded and protected in the insulation layer 33 such that a connection terminal 34a of each wiring electrode 34 is exposed from a surface 33c (first surface) of the insulation layer 33 on the side bonded to the insulation layer 22.

The thermosetting resin used for the insulation layer 33 is not particularly limited, and is, for example, a thermosetting resin such as an epoxy resin, an acrylic resin, a methacrylic resin, a maleimide resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, or a melamine resin. Among them, the thermosetting resin used for the insulation layer 33 is preferably an epoxy resin.

The inorganic oxide particles contained in the insulation layer 33 are not particularly limited, and are, for example, inorganic fillers such as silica (SiO₂), alumina (Al₂O₃), titania (TiO₂), tantalum oxide (Ta₂O₅), zirconia (ZrO₂), and zinc oxide (ZnO). The inorganic oxide particles may be used alone or in combination of two or more types thereof. As an example, the inorganic oxide particles contained in the insulation layer 33 are silica fillers.

The content of the inorganic oxide particles contained in the insulation layer 33 is, for example, 15% by volume to 70% by volume with respect to the total volume of the insulation layer 33. When the content of the inorganic oxide particles is 15% by volume or more of the total volume, the ratio of the cured product of the thermosetting resin contained in the insulation layer 33 is reduced to suppress the linear expansion coefficient (CTE) of the insulation layer 13, and it is possible to reduce warpage when the heat is applied to the stack 1A. When the content of the inorganic oxide particles is 70% or less of the total volume, the bonding region between the thermosetting resins can be sufficiently ensured, and the bonding strength between the insulation layer 33 and the insulation layer 22 can be increased.

In the stack 1A, similarly to the stack 1, the wiring electrodes 34 and the wiring electrodes 23 are provided in each of the insulation layers 33 and 22 to correspond to each other, and when bonded as shown in FIG. 6, the connection terminals 34a and the connection terminals 23a are bonded to each other. The cured products 33a and 22a of the thermosetting resin contained in the insulation layers 33 and 22 are also bonded to each other. In the stack 1A, while the insulation layer 33 contains the cured product 33a of the thermosetting resin and the inorganic oxide particles 33b, the insulation layer 22 contains the cured product 22a of the thermosetting resin but contains no inorganic oxide particles (or contains the inorganic oxide particles less than the insulation layer 13), and the insulation layers 33 and 22 are bonded to each other. Therefore, the thermal expansion coefficient of the insulation layer 33 is suppressed by the inorganic oxide particles 33b contained in the insulation layer 33. In the stack 1A, since the thickness of the insulation layer 33 is thicker than the insulation layer 22, thermal expansion of the stack 1A as a whole can be reduced. On the other hand, since the insulation layer 22 contains no inorganic oxide particles or contains inorganic oxide particles in a small amount, it is possible to embed debris, suppress the surface unevenness, and improve the bonding force between the insulation layers 33 and 22 by the insulation layer 22. As described above, in the stack 1A, it is possible to obtain a stack in which the bonding strength between the insulation layers is increased while preventing the positional displacement when the insulation layers are bonded to each other.

In the stack 1A, contrary to the above-described form, an aspect in which the insulation layer 33 of the first member 30 contains substantially no inorganic oxide particles (or an aspect in which the inorganic oxide particles are contained in a content smaller than that of the inorganic oxide particles contained in the insulating layer 22) may be adopted. In this case, the insulation layer 22 of the second member 20 may contain inorganic oxide particles, and the content of the inorganic oxide particles contained in the insulation layer 22 may be, for example, 15% by volume to 70% by volume with respect to the total volume of the insulation layer 22. That is, in this modification example, the aspect in which the insulation layer 33 of the first member 30 contains the inorganic oxide particles and the aspect in which the insulation layer 22 of the second member 20 contains the inorganic oxide particles are reversed. Even in such a modification example, the same operation and effect as described above can be obtained.

### Method for Manufacturing Semiconductor Device

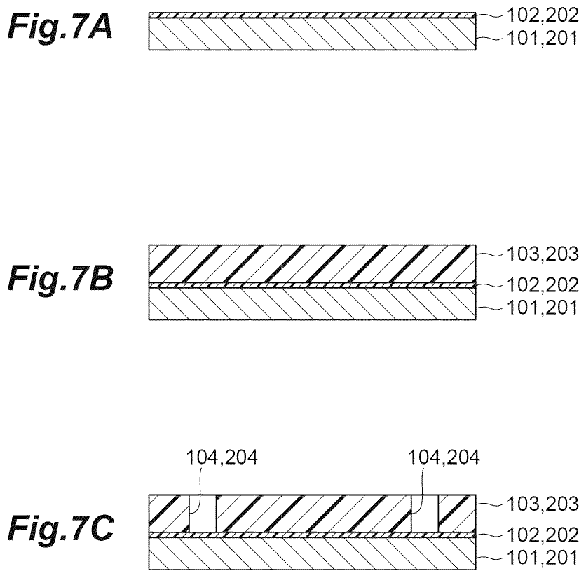

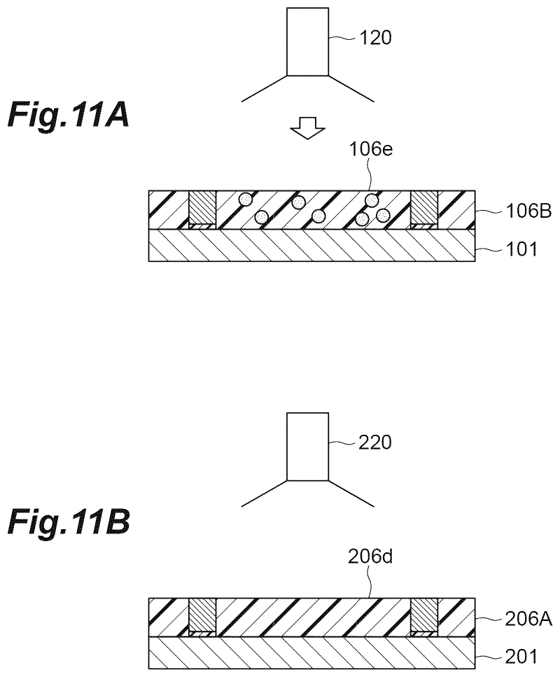

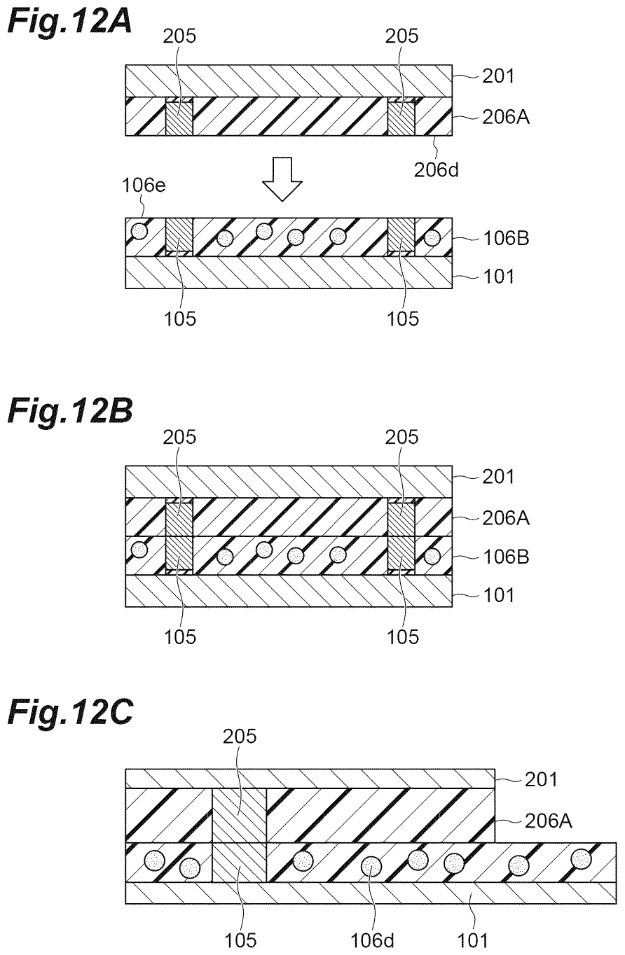

Next, a method for manufacturing the above-described stacks 1 and 1A (a method for manufacturing a stack) will be described in order with reference to FIGS. 7A to 7C to FIGS. 12A to 12C. FIGS. 7A to 7C to FIGS. 9A to 9D are views showing a method for manufacturing a first member used in manufacturing the stack. FIGS. 7A to 7C, FIGS. 8A to 8C, and FIGS. 10A to 10C are views showing a method for manufacturing a second member used in manufacturing the stack. FIGS. 11A and 11B and FIGS. 12A to 12C are views showing a method for manufacturing a stack. In the following description, a method for manufacturing a connection structure part between the first member 10 and the second member 20 will be mainly described, and regarding the description of manufacturing the interposer substrate 11, the insulation layer 12, the TSV 15, and the like, the manufacturing is possible using a conventional technique, and thus the description thereof will be omitted. The same applies to the method for manufacturing the connection structure part between the first member 30 and the second member 20, and thus the description thereof may be omitted.

First, the first member 10 is manufactured. In order to manufacture the first member 10, as shown in FIG. 7A, a seed layer 102 is formed on a support substrate 101 (first support substrate). The seed layer 102 is a part serving as a seed when electrolytic copper plating to be described later is formed, and is formed of, for example, nickel or the like. The support substrate 101 is not particularly limited, but is, for example, a highly rigid substrate such as a silicon plate or a glass plate. The thickness of the support substrate 101 is not particularly limited, and is, for example, 0.2 mm to 2.0 mm. When the support substrate 101 is 0.2 mm or more, handleability of the support substrate 101 can be improved. When the support substrate 101 is 2.0 mm or less, the material cost can be suppressed and the cost can be reduced. The support substrate 101 may have a wafer shape or a panel shape. The size of the support substrate 101 is not particularly limited, but may be, for example, a wafer having a diameter of 200 mm, a diameter of 300mm, or a diameter of 450 mm, or a rectangular panel having a side of 300mm to 700 mm. The support substrate 101 corresponds to, for example, the interposer substrate 11 of the first member 10.

Subsequently, as shown in FIG. 7B, a photosensitive resist is applied onto the seed layer 102 to form a resist layer 103. As the photosensitive resist, a known material can be appropriately used.

Thereafter, as shown in FIG. 7C, exposure is performed to form vias 104 in regions corresponding to the wiring electrodes. As a result, the vias 104 from which the seed layer 102 is exposed are formed.

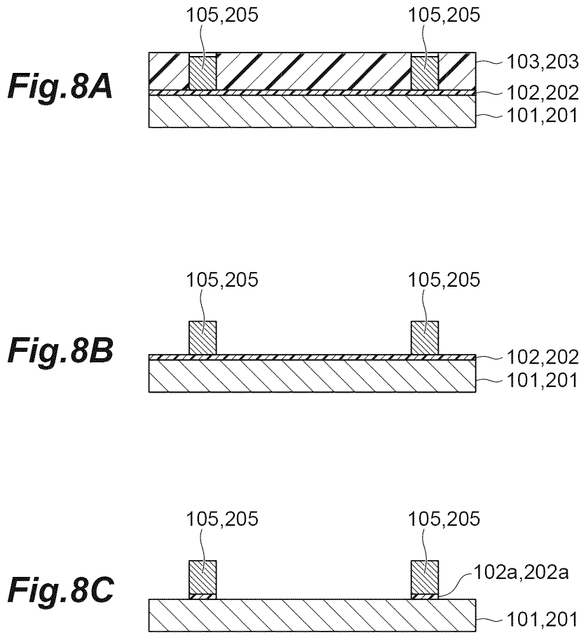

Subsequently, as shown in FIG. 8A, wiring electrodes 105 (first wiring electrode) are formed on the seed layer 102 in the vias 104 by electrolytic copper plating. Thereafter, as shown in FIGS. 8B and 8C, the resist layer 103 is removed by peeling, and the seed layer 102 at a part other than the wiring electrodes 105 is removed by etching. As described above, the wiring electrodes 105 each including the seed part 102a are formed on the support substrate 101. The method for forming the wiring electrodes 105 is not limited thereto, and the wiring electrodes 105 may be formed by another method. The wiring electrodes 105 formed in this manner can function as a wiring pad, an electrode pad, a connection bump, a pillar, or the like.

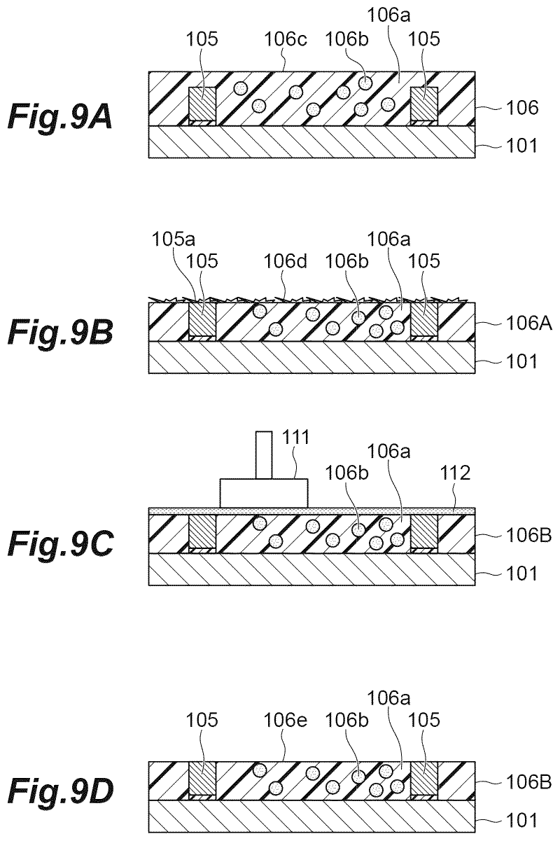

Subsequently, as shown in FIG. 9A, an insulation layer 106 is formed on the support substrate 101 such that the wiring electrodes 105 are encapsulated with an organic insulation material (first insulation material) containing a thermosetting resin 106a (first thermosetting resin) and inorganic oxide particles 106b (first inorganic oxide particles). At this time, the wiring electrodes 105 may be completely covered with the organic insulation material. In this formation, the organic insulation layer 106 containing the thermosetting resin 106a and the inorganic oxide particles 106b may be encapsulated by being formed in a mold by a compression type or transfer type molding machine. Alternatively, the organic insulation layer 106 containing the thermosetting resin 106a and the inorganic oxide particles 106b molded into a film shape may be encapsulated by a roll type or pressure type stack molding machine. The support substrate 101 formed to be encapsulated is heated using an oven, a hot plate, or the like. As a result, the organic insulation layer 106 containing the thermosetting resin 106a and the inorganic oxide particles 106b is formed on the support substrate 101. By this heating, the thermosetting resin of the organic insulation layer 106 may be in a state of being completely cured, or may be in a state of not being completely cured (for example, semi-curing, B-stage).

The materials of the thermosetting resin 106a and the inorganic oxide particles 106b constituting the organic insulation layer 106 are not particularly limited, but are encapsulating materials that can be formed in a mold by, for example, a compression type or transfer type molding machine from the viewpoint of high rigidity and embeddability. Alternatively, the material constituting the organic insulation layer 106 may be a encapsulating material molded into a film shape, a buildup material, or a solder resist material. In that case, from the viewpoint of preventing entrapment of bubbles, a film-shaped material may be laminated on the support substrate 101 under reduced pressure.

The thermosetting resin constituting the organic insulation layer 106 is not particularly limited, and, for example, an epoxy resin, an acrylic resin, a methacrylic resin, a maleimide resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, or a melamine resin can be used. The thermosetting resin used for the organic insulation layer 106 is preferably an epoxy resin among the above-described thermosetting resins.

The thermosetting resin may contain a crosslinking agent that is crosslinked by heat. Although not particularly limited, a known crosslinking agent can be used, and for example, an epoxy compound, an isocyanate compound, a phenol resin, a phenoxy resin, an unsaturated polyester resin, an alkyd resin, a urethane resin, a melamine resin, a urea resin, a guanamine resin, a polyimide resin, a polyamide resin, a vinyl ester resin, a diallyl phthalate resin, or the like may be used, or two or more thereof may be used in combination.

The inorganic oxide particles constituting the organic insulation layer 106 are not particularly limited, and, for example, inorganic fillers such as silica (SiO₂), alumina (Al₂O₃), titania (TiO₂), tantalum oxide (Ta₂O₅), zirconia (ZrO₂), and zinc oxide (ZnO) can be used. The inorganic oxide particles may be used alone or in combination of two or more types thereof. As an example, the inorganic oxide particles contained in the organic insulation layer 106 are silica fillers.

The content of the inorganic oxide particles contained in the organic insulation layer 106 is, for example, 15% by volume to 70% by volume of the total volume of the organic insulation material constituting the organic insulation layer 106. When the content of the inorganic oxide particles is 15% by volume or more of the total volume, it is possible to suppress an increase in the linear expansion coefficient (CTE) of the entire organic insulation layer 106 and to reduce warpage after a encapsulating step and a stacking step. When the content of the inorganic oxide particles is 70% by volume or less of the total volume, a sufficient bonding strength can be obtained by ensuring a bonding area between the thermosetting resins when the surfaces of the polished substrates are pressure-bonded while being heated in the bonding step to be described later. The organic insulation material used for forming the organic insulation layer 106 may be adjusted to have a thermal expansion coefficient of 40×10⁻⁶/K or less by containing the inorganic oxide particles as described above.

Materials of the thermosetting resin and the inorganic oxide particles constituting the organic insulation layer 106 are not particularly limited, but may be selected according to a semiconductor package structure to be applied. For example, in the case of a semiconductor package in which a memory is stacked on an interposer substrate to which an encapsulating material (stack 1A or the like) is applied, when an encapsulating material constituting the interposer and an encapsulating material formed to cover a memory chip are stacked, the encapsulating materials are stacked on each other by applying the above-described manufacturing method.

The thickness of the organic insulation layer 106 is, for example, 10 μm to 400 μm. When the thickness of the organic insulation layer 106 is 10 μm or more, a bonding force when the organic insulation layer 106 is bonded to another organic insulation layer can be ensured. When the thickness of the organic insulation layer 106 is 400 μm or less, the warpage of the entire substrate can be reduced, and the organic insulation layer can be easily adsorbed to the device in the subsequent grinding step.

Subsequently, as shown in FIGS. 9A and 9B, a surface 106c of the organic insulation layer 106 formed on the support substrate 101 is ground to make the organic insulation layer 106 have a predetermined thickness. This grinding is performed, for example, by a method of grinding using a grindstone rotating at a high speed. By this grinding step, surfaces 105a of the wiring electrodes 105 are exposed from a surface 106d of an organic insulation layer 106A. As the surface roughness of the organic insulation layer 106A containing the thermosetting resin 106a and the inorganic oxide particles 106b subjected to the grinding treatment, the arithmetic average roughness Ra when measured at a magnification of 20 times using a laser microscope is 0.5 μm or less from the viewpoint of grinding variation in the subsequent polishing treatment. In FIG. 9B, a state where the surface 106d has a certain degree of roughness is emphasized. The arithmetic average roughness Ra used here is an arithmetic average roughness (Ra) defined in JIS B 0601 2001.

Subsequently, as shown in FIG. 9C, the surface 106d of the organic insulation layer 106A containing the thermosetting resin 106a and the inorganic oxide particles 106b is polished and planarized by chemical mechanical polishing (CMP) using a polishing liquid. In this polishing step, the surface 106d of the organic insulation layer 106A containing the thermosetting resin 106a and the inorganic oxide particles 106b is planarized. This polishing step is performed, for example, by polishing the portion to be polished while supplying the polishing liquid 112 between a polishing pad 111 (polishing cloth) and the portion to be polished (organic insulation layer 106A) on the support substrate 101. As the polishing liquid 112 for CMP, various types of polishing liquids can be used. The polishing liquid for CMP is classified according to the type of abrasive grains (polishing particles) contained, and examples of the abrasive grains include cerium oxide (ceria) particles, silicon oxide (silica) particles, aluminum oxide (alumina) particles, and organic resin particles. From the viewpoint of the polishing speed, for example, ceria-based particles are applied as the abrasive grains.

By such polishing, the surface of the surface 106d of the organic insulation layer 106A may be polished, and the arithmetic average roughness Ra of a surface 106e may be 50 nm or less. When the arithmetic average roughness Ra of the surface 106e of an organic insulation layer 106B is 50 nm or less, it is possible to suppress the detachment of the filler in the organic insulation layer 106B and the insufficient grinding of the filler surface. In addition, it is possible to prevent generation of a gap at the bonding interface between the organic insulation layers due to abrasion of the surface 106e of the organic insulation layer 106B or the like, and to more reliably bond the organic insulation layers to be described later to each other. The arithmetic average roughness Ra of the organic insulation layer 106B subjected to the polishing treatment may be 50 nm or less, and polishing or grinding may be performed by a method other than CMP. For example, grinding by a fly cut method can be applied. In addition, the fly cut method may be combined with etching or the like.

The thickness of the organic insulation layer 106B subjected to the above-described grinding and polishing steps is, for example, 1 μm to 300 μm. When the thickness of the organic insulation layer 106B is 1 μm or more, the yield can be increased without excessively grinding the embedded wiring and electrode. Since the thickness of the organic insulation layer 106B is 300 μm or less, warpage of the entire substrate is prevented, and it is possible to prevent generation of voids at a contact interface in a pressure-bonding step to be described later, which makes it impossible to perform pressure-bonding. Thus, the first member 10 is formed.

As shown in FIG. 11A, the polished surface 106e of the organic insulation layer 106B may be irradiated with plasma (O₂ or Ar) or ultraviolet ray (UV) from an irradiator 120. In the case of irradiation with ultraviolet rays, the surface of the resin material constituting the organic insulation layer 106B reacts with ozone generated by the irradiation with the ultraviolet rays, the surface free energy increases, and a highly reactive functional group is generated on the surface 106e of the organic insulation layer 106B. As a result, the cured product of the thermosetting resin constituting the organic insulation layer 106B is in a state close to that before curing. Therefore, the bonding strength can be increased when the organic insulation layer 106B is bonded to an organic insulation layer 206A. In the case of irradiation with ultraviolet rays, unlike the plasma treatment, the surface 106e of the organic insulation layer 106B is not roughened, and thus bonding between the organic insulation layer 106B and the organic insulation layer 206A is not hindered. Since the bonding between the organic insulation layer 106B and the organic insulation layer 206A is enhanced by ultraviolet irradiation, the heating temperature at the time of bonding the organic insulation layer 106B and the organic insulation layer 206A to each other can be lowered as compared with the conventional case, or the heating time can be shortened. For example, the heating temperature at the time of bonding the organic insulation layer 106B and the organic insulation layer 206A to each other by ultraviolet irradiation can be set to 250° C. or lower. Accordingly, it is possible to simplify the bonding process and to suppress the influence of heating on the stack (or semiconductor device).

Next, similarly to the first member 10, the second member 20 is manufactured. In order to manufacture the second member 20, a seed layer 202 is formed on a support substrate 201 (second support substrate) as shown in FIG. 7A, similarly to the method of manufacturing the first member 10 (first half). The seed layer 202 is a part serving as a seed when electrolytic copper plating to be described later is formed, and is formed of, for example, nickel or the like. The support substrate 201 is not particularly limited, but is, for example, a silicon wafer on which a semiconductor chip or the like is formed. The thickness of the support substrate 201 is not particularly limited, and is, for example, 0.2 mm to 2.0 mm. The support substrate 201 may have a wafer shape or a panel shape. The size of the support substrate 201 is not particularly limited, but may be, for example, a wafer having a diameter of 200 mm, a diameter of 300 mm, or a diameter of 450 mm, or a rectangular panel having a side of 300 mm to 700 mm. The support substrate 201 corresponds to, for example, the semiconductor chip 21 of the second member 20.

Subsequently, as shown in FIG. 7B, a photosensitive resist is applied onto the seed layer 202 to form a resist layer 203. As the photosensitive resist, a known material can be appropriately used. Thereafter, as shown in FIG. 7C, exposure is performed to form vias 204 in regions corresponding to the wiring electrodes. As a result, the vias 204 from which the seed layer 202 is exposed is formed.

Subsequently, as shown in FIG. 8A, wiring electrodes 205 (second wiring electrode) are formed on the seed layer 202 in the vias 204 by electrolytic copper plating. Thereafter, as shown in FIGS. 8B and 8C, the resist layer 203 is removed by peeling, and the seed layer 202 at a part other than the wiring electrodes 205 is removed by etching. As described above, the wiring electrodes 205 each including a seed part 202a are formed on the support substrate 201. The wiring electrodes 205 may be formed in another direction similarly to the wiring electrodes 105.

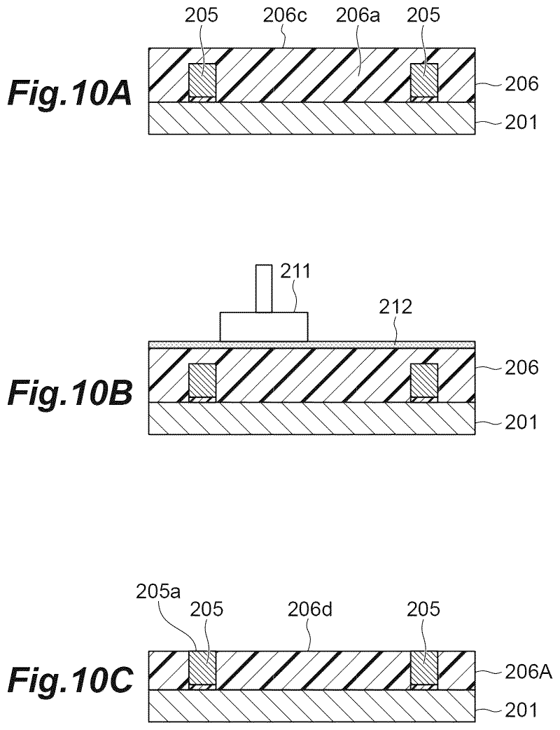

Subsequently, as shown in FIG. 10A, an insulation layer 206 is formed on the support substrate 201 such that the wiring electrodes 205 are encapsulated with an organic insulation material (second insulation material) made of a thermosetting resin (second thermosetting resin). At this time, the wiring electrodes 205 may be completely covered with the organic insulation material. In this formation, the organic insulation layer 206 containing a thermosetting resin 206a may be encapsulated by being formed in a mold by a compression type or transfer type molding machine. Alternatively, the organic insulation layer 206 molded into a film shape may be encapsulated by a roll type or pressure type stack molding machine. The support substrate 201 formed to be encapsulated is heated using an oven, a hot plate, or the like. As a result, the organic insulation layer 206 containing the thermosetting resin and the inorganic oxide particles is formed on the support substrate 201. By this heating, the thermosetting resin of the organic insulation layer 206 may be in a state of being completely cured, or may be in a state of not being completely cured (for example, semi-curing, B-stage).

The materials of the thermosetting resin constituting the organic insulation layer 206 are not particularly limited, but are encapsulating materials that can be formed in a mold by, for example, a compression type or transfer type molding machine from the viewpoint of high rigidity and embeddability. Alternatively, the material constituting the organic insulation layer 206 may be an encapsulating material molded into a film shape, a buildup material, or a solder resist material. In that case, from the viewpoint of preventing entrapment of bubbles, a film-shaped material may be laminated on the support substrate 201 under reduced pressure.

The thermosetting resin constituting the organic insulation layer 206 is not particularly limited, and, for example, an epoxy resin, an acrylic resin, a methacrylic resin, a maleimide resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, or a melamine resin can be used. The thermosetting resin used for the organic insulation layer 206 is preferably an epoxy resin among the above-described thermosetting resins.

The thermosetting resin may contain a crosslinking agent that is crosslinked by heat. Although not particularly limited, a known crosslinking agent can be used, and for example, an epoxy compound, an isocyanate compound, a phenol resin, a phenoxy resin, an unsaturated polyester resin, an alkyd resin, a urethane resin, a melamine resin, a urea resin, a guanamine resin, a polyimide resin, a polyamide resin, a vinyl ester resin, a diallyl phthalate resin, or the like may be used, or two or more thereof may be used in combination.

As described above, the organic insulation material forming the organic insulation layer 206 preferably contains substantially no inorganic oxide particles, but may contain inorganic oxide particles having a content lower than that of the inorganic oxide particles 106b contained in the organic insulation layer 106. In this case, the content of the inorganic oxide particles in the organic insulation material constituting the organic insulation layer 206 may be one fifth (⅕) or less of the content of the inorganic oxide particles 106b contained in the organic insulation material constituting the organic insulation layer 106. The content of the inorganic oxide particles in the organic insulation material constituting the organic insulation layer 206 may be 5% by volume or less.

Subsequently, as shown in FIG. 10B, a surface 206c of the organic insulation layer 206 formed on the support substrate 201 is polished to make the organic insulation layer 206 have a predetermined thickness. In this polishing, the surface 206c of the organic insulation layer 206 containing a thermosetting resin is polished and planarized by chemical mechanical polishing (CMP) using a polishing liquid. In this polishing step, the surface 206c of the organic insulation layer 206 containing the thermosetting resin is planarized. This polishing step is performed, for example, by polishing the portion to be polished while supplying the polishing liquid 212 between a polishing pad 211 (polishing cloth) and the portion to be polished (organic insulation layer 206) on the support substrate 201. As the polishing liquid for CMP, various types of polishing liquids can be used. The polishing liquid for CMP is classified according to the type of abrasive grains (polishing particles) contained, and examples of the abrasive grains include cerium oxide (ceria) particles, silicon oxide (silica) particles, aluminum oxide (alumina) particles, and organic resin particles. From the viewpoint of the polishing speed, for example, ceria-based particles are applied as the abrasive grains.

By such polishing, the surface 205a of the wiring electrodes 205 are exposed from a surface 206d of the organic insulation layer 206A. The surface of the surface 206d of the organic insulation layer 206A may be polished, and the arithmetic average roughness Ra of the surface 206d may be 50 nm or less. When the arithmetic average roughness Ra of the surface 206d of the organic insulation layer 206A is 50 nm or less, it is possible to prevent generation of a gap at the bonding interface between the organic insulation layers due to abrasion of the surface 206d of the organic insulation layer 206A or the like, and to more reliably bond the organic insulation layers to be described later to each other. The arithmetic average roughness Ra of the organic insulation layer 206A subjected to the polishing treatment may be 50 nm or less, and polishing or grinding may be performed by a method other than CMP. For example, grinding by a fly cut method can be applied. The fly cut method may be combined with etching or the like. In the manufacturing of the second member 20, when the inorganic oxide particles are not contained, the grinding step in the manufacturing of the first member 10 may not be performed, but when the inorganic oxide particles are contained, the same grinding step may be performed.

The thickness of the organic insulation layer 206A subjected to the above-described polishing step is, for example, 1 μm to 300 μm. When the thickness of the organic insulation layer 206A is 1 μm or more, the yield can be increased without excessively grinding the embedded wiring and electrode. Since the thickness of the organic insulation layer 206A is 300 μm or less, warpage of the entire substrate is suppressed, and it is possible to prevent generation of voids at a contact interface in a pressure-bonding step to be described later, which makes it impossible to perform pressure-bonding. Thus, the second member 20 is formed.

As shown in FIG. 11B, the polished surface 206d of the organic insulation layer 206A may be irradiated with plasma (O₂ or Ar) or ultraviolet ray (UV) from an irradiator 220. In the case of irradiation with ultraviolet rays, the surface of the resin material constituting the organic insulation layer 206A reacts with ozone generated by the irradiation with the ultraviolet rays, the surface free energy increases, and a highly reactive functional group is generated on the surface 206d of the organic insulation layer 206A. As a result, the cured product of the thermosetting resin constituting the organic insulation layer 206A is in a state close to that before curing. Therefore, the bonding strength can be increased when the organic insulation layer 206A is bonded to the organic insulation layer 106B. In the case of irradiation with ultraviolet rays, unlike the plasma treatment, the surface 206d of the organic insulation layer 206A is not roughened, and thus bonding between the organic insulation layer 106B and the organic insulation layer 206A is not hindered. Since the bonding between the organic insulation layer 106B and the organic insulation layer 206A is enhanced by ultraviolet irradiation, the heating temperature at the time of bonding the organic insulation layer 106B and the organic insulation layer 206A to each other can be lowered as compared with the conventional case, or the heating time can be shortened. Accordingly, it is possible to simplify the bonding process and to suppress the influence of heating on the stack (or semiconductor device, semiconductor chip). Since the organic insulation layer 206A contains no organic oxide particles or a trace amount of inorganic oxide particles, the effect of surface modification by ultraviolet irradiation can be made higher than that of the organic insulation layer 106A.

Subsequently, when the first member 10 and the second member 20 of which surfaces are planarized in the polishing step are prepared, as shown in FIG. 12A, the surface 106e of the organic insulation layer 106B of the first member 10 and the surface 206d of the organic insulation layer 206A of the second member 20 are bonded to each other by heating and pressurizing (pressure-bonding). At the time of this bonding, pressure-bonding may be performed under a nitrogen atmosphere. By setting the oxygen concentration at the time of performing this pressure-bonding to 1,000 ppm or less, it is possible to prevent the surfaces of the wiring electrodes 105 and 205, the thermosetting resin, and the inorganic oxide particles exposed by the polishing step from being oxidized, and accordingly, it is possible to reduce bonding failure.

In this bonding step, the heating temperature at the time of pressure-bonding the planarized organic insulation layers 106B and 206A is, for example, 200° C. to 400° C. When the heating temperature at the time of pressure-bonding is 200° C. or higher, insufficient melting of the resin and poor bonding between the wiring layers can be prevented, and the bonding strength between the organic insulation layers 106B and 206A can be increased. When the heating temperature at the time of pressure-bonding is 400° C. or lower, it is possible to prevent the thermosetting resin and the like in the organic insulation layers 106B and 206A from being decomposed, and it is possible to more reliably bond the thermosetting resins to each other. When the surface modification is performed by irradiating the surfaces 106e and 206d of the organic insulation layers 106B and 206A with ultraviolet rays after the polishing step, the heating temperature and the heating time at the time of bonding can be shortened. In this case, the heating temperature at the time of pressure-bonding the planarized organic insulation layers 106A and 206A can be, for example, 300° C. or lower. The heating time can be within 15 minutes.

In this bonding step, the applied pressure at the time of pressure-bonding the planarized organic insulation layers 106B and 206A in the polishing step is, for example, 5.0 MPa to 100 MPa. When the applied pressure is 5.0 MPa or more, the organic insulation layers 106B and 206A planarized by CMP can be sufficiently brought into contact with each other even when there is an influence of warpage or the like, and sufficient bonding strength can be obtained. When the applied pressure is 100 MPa or less, it is possible to prevent the substrate planarized by CMP from being damaged.

In this bonding step, after the pressure-bonding, additional heating may be further performed in a nitrogen atmosphere as necessary. The heating temperature after the pressure-bonding is, for example, 250° C. to 400° C., and the heating time after the pressure-bonding is, for example, 30 minutes to 180 minutes. By heating at a temperature of 250° C. or higher, the embedded wiring electrodes 105 and 205 can be firmly bonded to each other by metal bonding. By setting the heating temperature to 400° C. or lower, it is possible to prevent the resin components of the organic insulation layers 106B and 206A from being decomposed by heat. By the heating at the time of additional heating or pressure-bonding, the thermosetting resin in the organic insulation layers 106B and 206A is completely cured. As described above, for example, the stack 1 and the stack 1A are manufactured.

The materials constituting the thermosetting resin of the organic insulation layers 106B and 206A to be bonded in the above-described bonding step may be the same, and in the case where the materials are the same, the bonding strength at the time of bonding the organic insulation layers 106B and 206A to each other can be easily increased. On the other hand, the thermosetting resins constituting the organic insulation layers 106B and 206A to be bonded in the above-described bonding step may be different from each other.

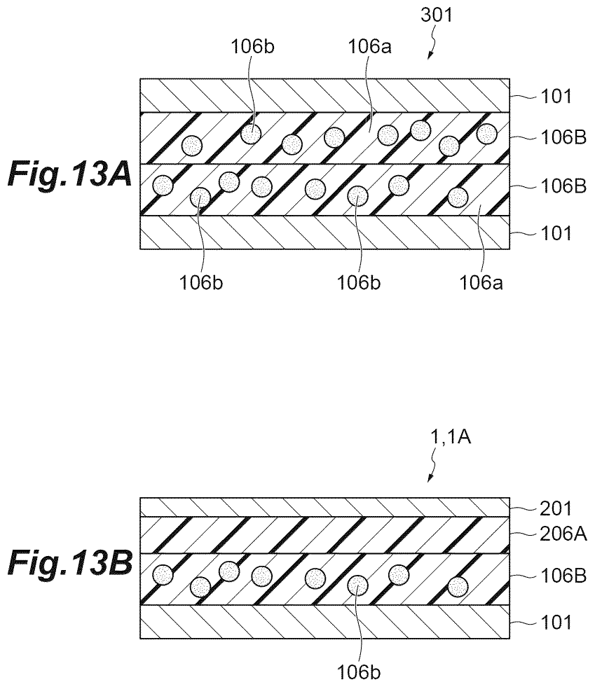

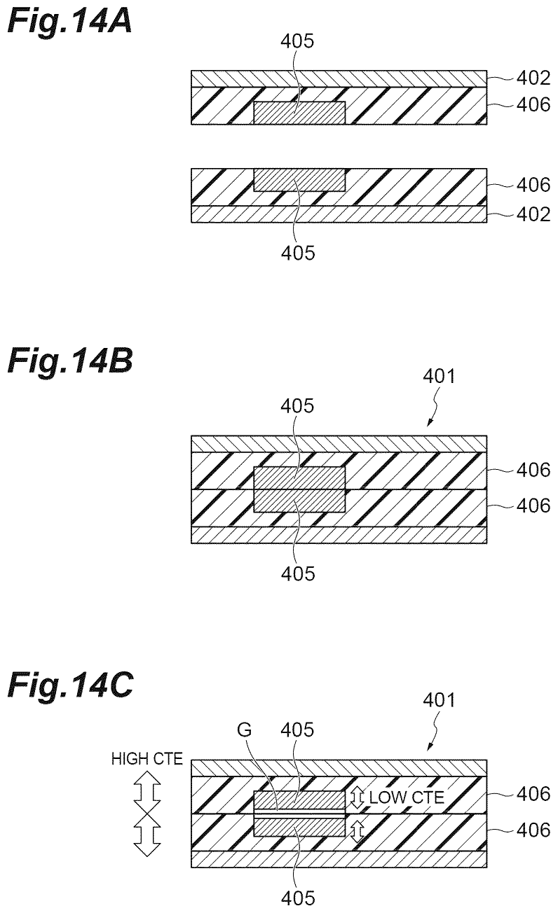

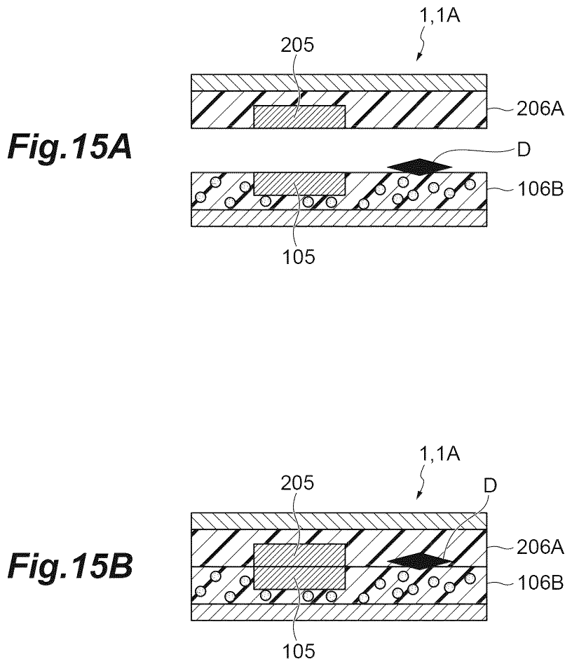

Here, the effects of the method for manufacturing a stack according to the present embodiment will be described with reference to FIGS. 13A and 13B to FIGS. 15A and 15B. FIG. 13A is a cross-sectional view showing the stack manufactured by another manufacturing method, and FIG. 13B is a cross-sectional view showing a stack manufactured by a manufacturing method according to the present embodiment. In FIG. 13A, similar inorganic oxide particles 106b are contained in both insulation layers 106B bonded to each other. FIGS. 14A to 14C are views showing another stack manufacturing method and an influence of thermal expansion in a stack manufactured by the manufacturing method. FIGS. 15A and 15B are views for describing a situation of embedding of a foreign substance by the manufacturing method according to the present embodiment.

First, the bonding strength will be described with reference to FIGS. 13A and 13B. As shown in FIG. 13A, when both the insulation layers 106B bonded to each other contain the inorganic oxide particles 106b of the same degree, the thermal expansion coefficient of the thermosetting resin 106a can be reduced, but it is considered that the area of the bonding region in the resin part such as the thermosetting resin is reduced in the entire stack 1. That is, the region where the resin part in one organic insulation layer and the cross-sectional part of the inorganic oxide particle in the other organic insulation layer are in contact with each other inevitably increases, and accordingly, the area where the resin part in one organic insulation layer and the resin part in the other organic insulation layer are bonded to each other decreases. Therefore, in the aspect shown in FIG. 13A, it may be difficult to further improve the bonding strength in the stack 1. On the other hand, according to the aspect shown in FIG. 13B, one organic insulation layer 206A contains no inorganic oxide particles (or only contains some inorganic oxide particles). Therefore, the area where the resin part in one organic insulation layer 206A and the resin part in the other organic insulation layer 106B are bonded to each other can be made relatively wide. Thus, according to the manufacturing method of the present embodiment, the bonding strength between the organic insulation layers 106B and 206A can be increased.

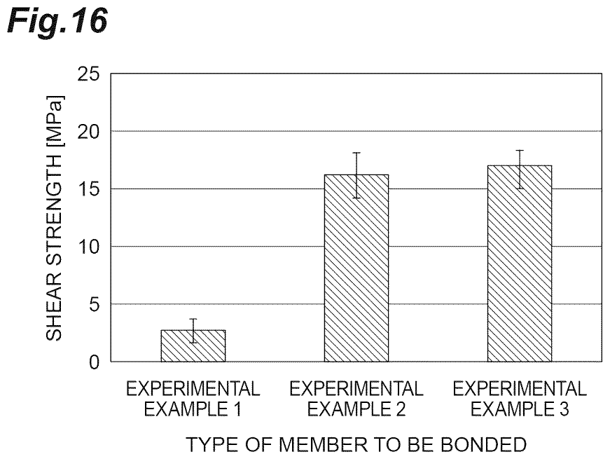

For example, as shown in FIG. 16, in a case where a stack was manufactured by another manufacturing method shown in FIG. 13A (Experimental Example 1), the shear strength was 5 MPa or less, whereas in a case where a stack was manufactured by the manufacturing method according to the present embodiment shown in FIG. 13B (Experimental Example 2), the shear strength was 15 MPa or more. Although Experimental Example 3 shows the shear strength when the organic insulation layers not containing inorganic oxide particles are bonded to each other, it has been confirmed that the manufacturing method (Experimental Example 2) according to the present embodiment can achieve the same bonding strength as that of Experimental Example 3. In Experimental Example 2, the organic insulation layers 106B and 206A were irradiated with ultraviolet rays (refer to FIGS. 11A and 11B). The shear strength in the case of bonding the inorganic insulation layers (silicon substrates) to each other is, for example, about 15 MPa, and it has been confirmed that the same bonding strength can be obtained according to the present embodiment.

Next, reduction of the thermal expansion coefficient will be described with reference to FIGS. 14A to 14C. As shown in FIGS. 14A and 14B, in the case of the stack 401 in which the inorganic oxide fine particles are not contained in any of the organic insulation layers 406 formed on the support substrate 402, as shown in FIG. 14C, the thermal expansion coefficient of the organic insulation material constituting the organic insulation layer 406 or the cured product thereof largely deviates from the thermal expansion coefficient of the wiring electrode 405. That is, in the stack 401, the organic insulation material constituting the organic insulation layer 406 or a cured product thereof has a large thermal expansion coefficient, whereas the wiring electrode 405 (for example, copper) has a small thermal expansion coefficient. For this reason, when the stack 401 generates heat or is heated in the manufacturing step, the expansion of the wiring electrodes 405 does not catch up with the expansion of the organic insulation material, such that an interface between the wiring electrodes 405 may be poor in bonding, or positional displacement may occur in the organic insulation layer 406 during manufacturing. On the other hand, according to the method for manufacturing the stacks 1 and 1A according to the present embodiment, the inorganic oxide particles are contained in one insulation layer, and the thermal expansion coefficient of at least one insulation layer is reduced. Therefore, when the stacks 1 and 1A generate heat or is heated in the manufacturing step, it is possible to prevent the case where the expansion of the wiring electrodes 14, 23, 34, 105, and 205 does not catch up with the expansion of the organic insulation material, such that an interface between the wiring electrodes 14, 23 and the like may be poor in bonding, or positional displacement may occur in the organic insulation layer during manufacturing.

As shown in FIG. 13A, when inorganic oxide fine particles are contained in both organic insulation layers, softness of the organic insulation layer in the stack is reduced, and it may be difficult to embed a foreign substance D and the like by the organic insulation layer. On the other hand, according to the stack manufacturing method of the present embodiment, the other insulation layer contains no inorganic oxide particles, or the other insulation layer only contains a small amount of inorganic oxide, and has a lower elastic modulus (for example, 10 GPa or less) than that of the one insulation layer. Therefore, even when dust or the like is generated when the stacks 1 and 1A are manufactured by bonding, such foreign substances can be more reliably contained by the organic insulation layer not containing inorganic oxides or the like. Accordingly, it is possible to reduce connection failure caused by foreign substances or the like.

Above, according to the method for manufacturing a stack according to the present embodiment, while the organic insulation layer 106B contains the thermosetting resin 106a and the inorganic oxide particles 106b, the organic insulation layer 206A contains the thermosetting resin 206a but contains no inorganic oxide particles, or contains the inorganic oxide particles less than the organic insulation layer 106B, and the organic insulation layers 106B and 206A are bonded to each other. In this case, the thermal expansion coefficient of the organic insulation layer 106B is suppressed by the inorganic oxide particles 106b contained in the organic insulation layer 106B. On the other hand, since the organic insulation layer 206A contains no inorganic oxide particles or contains inorganic oxide particles in a small amount, it is possible to embed debris, suppress the surface unevenness, and improve the bonding force between the insulation layers by the organic insulation layer 206A. According to the method for manufacturing a stack, it is possible to increase the bonding strength between insulation layers while preventing positional displacement when the insulation layers are bonded to each other.

In the method for manufacturing a stack according to the present embodiment, the content of the inorganic oxide particles in the organic insulation material constituting the organic insulation layer 206A may be one fifth (⅕) or less of the content of the inorganic oxide particles 106b contained in the organic insulation material constituting the organic insulation layer 106B. In this case, the organic insulation layer 206A can further embed debris, suppress the surface unevenness, and improve the bonding force between the insulation layers.

In the method for manufacturing a stack according to the present embodiment, the content of the inorganic oxide particles in the organic insulation material constituting the organic insulation layer 206A may be 5% by volume or less. In this case, the organic insulation layer 206A can further embed debris, suppress the surface unevenness, and improve the bonding force between the insulation layers.

In the method for manufacturing a stack according to the present embodiment, the organic insulation material constituting the organic insulation layer 206A preferably contains substantially no inorganic oxide particles. In this case, the organic insulation layer 206A can more reliably embed debris, suppress the surface unevenness, and improve the bonding force between the insulation layers.

In the method for manufacturing a stack according to the present embodiment, the organic insulation material for the organic insulation layer 106B containing the thermosetting resin 106a and the inorganic oxide particles 106b is preferably adjusted to have a thermal expansion coefficient smaller than that of the organic insulation material constituting the organic insulation layer 206A. In this case, since the thermal expansion coefficient in the organic insulation layer 106B can be reduced, positional displacement due to thermal expansion can be prevented. Accordingly, it is possible to obtain a stack with high bonding accuracy. In addition, in a case where a wiring such as copper (Cu) is provided in the stack, the expansion of the insulation material containing the thermosetting resin or the like may be larger than the expansion of the wiring, and the wiring may not be able to follow the expansion of the insulation layer, and a defect may occur in the bonding between the wirings. However, according to this manufacturing method, by reducing the thermal expansion coefficient of the insulation material for the organic insulation layer 106, a difference in thermal expansion between the insulation material and the wiring can be reduced, and bonding failure between the wirings can be prevented.

In the method for manufacturing a stack according to the present embodiment, the organic insulation material for the organic insulation layer 106B containing the thermosetting resin 106a and the inorganic oxide particles 106b is preferably adjusted to have a thermal expansion coefficient of 40×10⁻⁶/K or less. In this case, since the thermal expansion coefficient in the organic insulation layer 106B can be reduced, positional displacement due to thermal expansion can be prevented. Accordingly, it is possible to obtain a stack with high bonding accuracy. In addition, in a case where a wiring such as copper (Cu) is provided in the stack, the expansion of the insulation material containing the thermosetting resin or the like may be larger than the expansion of the wiring, and the wiring may not be able to follow the expansion of the insulation layer, and a defect may occur in the bonding between the wirings. However, according to this manufacturing method, by reducing the thermal expansion coefficient of the first insulation material, a difference in thermal expansion between the insulation material and the wiring can be reduced, and bonding failure between the wirings can be prevented.

In the method for manufacturing a stack according to the present

embodiment, the content of the inorganic oxide particles 106b in the insulation material for the organic insulation layer 106B containing the thermosetting resin 106a and the inorganic oxide particles 106b is preferably 15% by volume to 70% by volume. In this case, since the thermal expansion coefficient in the organic insulation layer 106B can be reduced by containing the inorganic oxide particles, positional displacement due to thermal expansion can be prevented. Accordingly, it is possible to obtain a stack with high bonding accuracy. In addition, in a case where a wiring such as copper (Cu) is provided in the stack, the expansion of the insulation material containing the thermosetting resin or the like may be larger than the expansion of the wiring, and the wiring may not be able to follow the expansion of the insulation layer, and a defect may occur in the bonding between the wirings. However, according to this manufacturing method, by reducing the thermal expansion coefficient of the first insulation material, a difference in thermal expansion between the insulation material and the wiring can be reduced, and bonding failure between the wirings can be prevented.

The method for manufacturing a stack according to the present embodiment may further include a step of polishing and planarizing the surfaces 106d and 106e of the organic insulation layers 106 and 106A, and in the step of polishing the organic insulation layer 106 and 106A, the insulation layer may be polished such that the arithmetic average roughness of the surfaces 106d and 106e is 50 nm or less. When inorganic oxide particles are contained in the insulation layer, the surface roughness of the inorganic oxide particles may become rough, but in the present manufacturing method, one organic insulation layer is planarized by polishing or the like before bonding. Accordingly, it is possible to more reliably increase the accuracy and bonding strength when the organic insulation layer 106B is bonded to the organic insulation layer 206A. As a result, it is possible to more reliably increase the accuracy and bonding strength when the organic insulation layer 106B and the organic insulation layer 206A are bonded to each other.

In the method for manufacturing a stack according to the present embodiment, the support substrate 101 may include an inorganic interposer made of an inorganic material or an organic interposer made of an organic material containing inorganic oxide particles. In this case, by reducing the thermal expansion coefficient of the insulation layer on the interposer side, the difference in thermal expansion coefficient between the insulation layer and the interposer can be reduced, and defects in the interposer during package assembly, such as warpage, cracks, defective mounting, defective terminal connection, defective insulation layer formation, and interfacial peeling, can be eliminated. In addition, by reducing the thermal expansion coefficient of the insulation layer on the interposer side, the difference in thermal expansion coefficient between the insulation layer and the interposer can be reduced, and defects as a stack (or semiconductor device), such as deformation of wiring, connection breakdown, material peeling, wiring short, and material failure, can be eliminated.

In the method for manufacturing a stack according to the present embodiment, a semiconductor chip may be attached to a surface of the organic insulation layer 206A on a side opposite to the surface 206d. In this case, the insulation layer on the semiconductor chip side contains no inorganic oxide particles or contains a small amount of inorganic oxide particles, and it is possible to prevent adhesion of the particles to the semiconductor chip and occurrence of a connection failure or the like.

The method for manufacturing a stack according to the present embodiment may further include a step of polishing and planarizing the surfaces 106d and 106e of the organic insulation layer 106 and 106A; a step of forming the organic insulation layer 206 containing the thermosetting resin 206a on the support substrate 201; and a step of polishing and planarizing the surface 206c of the organic insulation layer 206. In the bonding step, the planarized surface 106e and the planarized surface 206d may be bonded to each other. When inorganic oxide particles are contained in the insulation layer, the surface roughness of the inorganic oxide particles may become rough, but in the present manufacturing method, the organic insulation layer is planarized by polishing or the like before bonding. Accordingly, it is possible to further increase the bonding strength between the organic insulation layer 106B and the organic insulation layer 206A.

The method for manufacturing a stack according to the present embodiment preferably further includes a step of irradiating the surface 206d of the organic insulation layer 206A with ultraviolet rays. In this case, the surface of the resin material constituting the organic insulation layer 206A reacts with ozone generated by the irradiation with the ultraviolet rays, the surface free energy increases, and a highly reactive functional group is generated on the surface 206d of the organic insulation layer 206A. In other words, the cured product of the thermosetting resin constituting the organic insulation layer 206A is in a state close to that before curing. Accordingly, it is possible to further increase the bonding strength between the organic insulation layer 106B and the organic insulation layer 206A. In the case of irradiation with ultraviolet rays, unlike the plasma treatment, the surface 206d of the organic insulation layer 206A is not roughened, and thus bonding between the organic insulation layer 106B and the organic insulation layer 206A is not hindered. However, surface treatment using plasma treatment may be performed. In this manufacturing method, since the bonding between the organic insulation layer 106B and the organic insulation layer 206A is enhanced by ultraviolet irradiation as described above, the heating temperature at the time of bonding the organic insulation layer 106B and the organic insulation layer 206A to each other can be lowered as compared with the conventional case, or the heating time can be shortened. Accordingly, it is possible to simplify the bonding process and to suppress the influence of heating on the stack (or semiconductor device).

In the method for manufacturing a stack according to the present embodiment, in the step of bonding the organic insulation layer 106B and the organic insulation layer 206A to each other, the organic insulation layer 106B and the organic insulation layer 206A may be bonded to each other by heating at 300° C. or lower. In this case, it is possible to suppress the influence of heating on the stack (or the semiconductor device).

The method for manufacturing a stack according to the present embodiment may further include a step of forming the wiring electrode 105 on the support substrate 101, and in the step of forming the organic insulation layer 106, the wiring electrode 105 may be encapsulated with an insulation material containing the thermosetting resin 106a and the inorganic oxide particles 106b. Accordingly, the wiring electrode 105 is protected by this insulation material.

The method for manufacturing a stack according to the present embodiment may further include a step of forming the wiring electrode 205 on the support substrate 201; and a step of forming the organic insulation layer 206 on the support substrate 201 to encapsulate the wiring electrode 205 with an insulation material containing the thermosetting resin 206a. In the bonding step, the connection terminal of the wiring electrode 105 and the connection terminal of the wiring electrode 205 may be bonded to each other when the surface 106e of the organic insulation layer 106B and the surface 106d of the organic insulation layer 206A are bonded to each other. In this case, both the connection terminals can be bonded to each other more reliably.

Although the embodiments of the present disclosure have been described above, the present invention is not limited to the above-described embodiments, and modifications may be appropriately made without departing from the gist thereof. For example, in the embodiment of the above-described method for manufacturing a stack, the organic insulation layers 106 and 106B contains the inorganic oxide particles 106b, and the organic insulation layers 206 and 206A contains no inorganic oxide particles or contains a trace amount of the inorganic oxide particles, but the aspect in which the inorganic oxide particles are contained may be reversed. Even in this case, a similar function and effect can be obtained.

### REFERENCE SIGNS LIST

1, 1A Stack
10, 30 First member
20 Second member
11 Interposer substrate
13, 22, 33, 106, 106B, 206, 206A Insulation layer
14, 23, 34, 105, 205 Wiring electrode
21 Semiconductor chip
13a, 22a, 33a Cured product
13b, 22b, 33b, 106b Inorganic oxide particle
101, 201 Support substrate
106a, 206a Thermosetting resin
112, 212 Polishing liquid
120, 220 Irradiator]

1. A method for manufacturing a stack, comprising:
forming a first insulation layer on a first support substrate, the first insulation layer including a first thermosetting resin and first inorganic oxide particles; and
bonding a first surface of the first insulation layer to a second surface of a second insulation layer including a second thermosetting resin,
wherein the second insulation layer includes substantially no inorganic oxide particles or includes second inorganic oxide particles in a content smaller than that of the first inorganic oxide particles included in the first insulation layer.

2. The method for manufacturing a stack according to claim 1,
wherein a content of the second inorganic oxide particles in a second insulation material forming the second insulation layer is one fifth or less of a content of the first inorganic oxide particles included in a first insulation material forming the first insulation layer.

3. The method for manufacturing a stack according to claim 1,
wherein the content of the second inorganic oxide particles in the second insulation material forming the second insulation layer is 5% by volume or less.

4. The method for manufacturing a stack according to claim 1,
wherein the second insulation material forming the second insulation layer includes substantially no inorganic oxide particles.

5. The method for manufacturing a stack according to claim 1,
wherein the first insulation material including the first thermosetting resin and the first inorganic oxide particles is adjusted to have a thermal expansion coefficient smaller than that of the second insulation material forming the second insulation layer.

6. The method for manufacturing a stack according to claim 1,
wherein the first insulation material including the first thermosetting resin and the first inorganic oxide particles is adjusted to have a thermal expansion coefficient of 40×10⁻⁶/K or less.

7. The method for manufacturing a stack according to claim 1,
wherein the content of the first inorganic oxide particles in the first insulation material including the first thermosetting resin and the first inorganic oxide particles is 15% by volume to 70% by volume.

8. The method for manufacturing a stack according to claim 1, further comprising:
planarizing the first surface of the first insulation layer,
wherein, in the planarizing the first insulation layer, the first insulation layer is polished such that the arithmetic average roughness of the first surface is 50 nm or less.

9. The method for manufacturing a stack according to claim 1,
wherein the first support substrate includes an inorganic interposer made of an inorganic material or an organic interposer made of an organic material containing inorganic oxide particles.

10. The method for manufacturing a stack according to claim 1,
wherein a semiconductor chip is attached to a surface of the second insulation layer on a side opposite to the second surface.

11. The method for manufacturing a stack according to claim 1, further comprising:
planarizing the first surface of the first insulation layer;
forming the second insulation layer including the second thermosetting resin on a second support substrate; and
planarizing the second surface of the second insulation layer,
wherein, in the bonding, the planarized first surface is bonded to the planarized second surface.

12. The method for manufacturing a stack according to claim 1, further comprising:
irradiating the second surface of the second insulation layer with ultraviolet rays.

13. The method for manufacturing a stack according to claim 1,
wherein, in the bonding the first surface to the second surface, the first insulation layer and the second insulation layer are bonded to each other by heating them at 250° C. or lower.

14. The method for manufacturing a stack according to claim 1, further comprising:
forming a first wiring electrode on the first support substrate,
wherein, in the forming the first insulation layer, the first wiring electrode is encapsulated with the first insulation material including the first thermosetting resin and the first inorganic oxide particles.

15. The method for manufacturing a stack according to claim 14, further comprising:
forming a second wiring electrode on the second support substrate; and
forming the second insulation layer on the second support substrate to encapsulate the second wiring electrode with the second insulation material including the second thermosetting resin,
wherein, in the bonding, when the first surface of the first insulation layer is bonded to the second surface of the second insulation layer, a connection terminal of the first wiring electrode is boned to a connection terminal of the second wiring electrode.

16-26. (canceled)
